(19) United States
(12) Patent Application Publication
(10) Pub. No.: US 2016/0268440 A1
(43) Pub. Date: Sep. 15, 2016

(54) THIN FILM TRANSISTOR AND FABRICATION METHOD THEREOF, ARRAY SUBSTRATE AND DISPLAY DEVICE

(71) Applicant: BOE TECHNOLOGY GROUP CO., LTD., Beijing (CN)

(72) Inventor: Xiang LIU, Beijing (CN)

(73) Assignee: BOE TECHNOLOGY GROUP CO., LTD., Beijing (CN)

(21) Appl. No.: 14/408,493

(22) PCT Filed: May 29, 2014
(86) PCT No.: PCT/CN2014/078859

§ 371 Date: Dec. 16, 2014

(30) Foreign Application Priority Data
Sep. 26, 2013 (CN) 201310446633.0

(51) Int. Cl. H01L 29/786; H01L 27/12; H01L 29/66

(52) U.S. Cl. CPC H01L 29/78606; H01L 29/7869; H01L 29/66969; H01L 27/1225; H01L 27/1262

(57) ABSTRACT

The disclosure discloses a thin film transistor and a fabrication method thereof, an array substrate and a display device. The thin film transistor comprises an active layer and an insulating layer adjacent to the active layer. The insulating layer comprises a first insulating layer, the first insulating layer comprises a first silicon oxide film and a second silicon oxide film, and the second silicon oxide film is in direct contact with the active layer. A density of the second silicon oxide film is larger than that of the first silicon oxide film.

### TECHNICAL FIELD

Embodiments of the disclosure relate to a thin film transistor and a fabrication method thereof, an array substrate and a display device.

### BACKGROUND

Flat-panel display has replaced the heavy Cathode Ray Tube (CRT) display and increasingly is applied in people's daily life. At present, the normal flat-panel display comprises Liquid Crystal Display (LCD) and Organic Light-Emitting Diode (OLED) display. The flat-panel displays of above two types are characterized in small volume, low power consumption, no radiation and so on, and are dominating in the current flat-panel display market.

As the rapid development of the flat-panel display, its dimension and resolution are continuously improved; meanwhile, a frequency of a driving circuit is also continuously increased. Generally, the mobility of amorphous-silicon thin-film transistor is about 0.5 cm²/V.S. In the case that the flat-panel display has a dimension of more than 80 inches and the driving frequency is 120 Hz, a mobility of over 1 cm²/V.S is required; in this case, the mobility of amorphous-silicon thin-film transistor apparently is very hard to meet such requirement. In addition, although studies on polysilicon thin-film transistor began relatively early, it has poor homogeneity and complex fabrication process. The metal oxide thin film transistor features high mobility, good homogeneity, good transparency, and simple fabrication process, and is capable of meeting the requirements of large-sized LCDs and OLED displays with high refresh rate on mobility.

Generally, silicon oxide (SiOₓ) is applied to prepare the gate insulating layer of the metal oxide thin film transistor; however, SiOₓ is slow in deposition rate and low in etching rate, so the SiOₓ film in the same thickness region has many defect, such as uneven density and the like. Along with the increase of the thickness of the SiOₓ film, the adverse influence caused by these defects becomes obvious, so that the interface between the SiOₓ film and the metal oxide film has many defect states, thereby influencing characteristics of the thin film transistor. Similarly, other insulating layers in contact with the metal oxide film, such as an etching barrier layer and a passivation layer, also have such problem.

### SUMMARY

According to embodiments of the disclosure, a thin film transistor is provided. The thin film transistor comprises an active layer and an insulating layer adjacent to the active layer. The insulating layer comprises a first insulating layer, the first insulating layer comprises a first silicon oxide film and a second silicon oxide film, the second silicon oxide film is in direct contact with the active layer; and a density of the second silicon oxide is larger than that of the first silicon oxide film.

For example, a thickness of the first insulating layer is 300 Å-1500 Å.

For example, a thickness of the second silicon oxide film is 300 Å-800 Å.

For example, the insulating layer further comprises a second insulating layer, the second insulating layer is disposed on a side of the first insulating layer away from the active layer, and the second insulating layer is formed of a silicon nitride film, a silicon oxynitride film or a combination thereof.

For example, the active layer is formed of a metal oxide semiconductor.

For example, the thin film transistor further comprises a gate electrode, and the insulating layer is disposed between the gate electrode and the active layer to serve as a gate insulating layer.

For example, the insulating layer is disposed on the active layer to serve as an etching barrier layer.

According to embodiments of the disclosure, an array substrate is provided. The array substrate comprises the thin film transistor as described above.

According to embodiments of the disclosure, a display device is provided. The display device comprises the array substrate as described above.

According to embodiments of the disclosure, a fabrication method of a thin film transistor is provided. The thin film transistor comprises an active layer and an insulating layer, the insulating layer comprises a first insulating layer formed of a first silicon oxide film and a second silicon oxide film. The method comprises a step of forming the active layer and a step of forming the insulating layer. The step of forming the insulating layer comprises: depositing the first silicon oxide film at a first rate, and depositing the second silicon oxide film at a second rate. The second silicon oxide film is in direct contact with the active layer, and the second rate is less than the first rate.

For example, the second rate is 1/5-4/5 of the first rate.

For example, when the first silicon oxide film is deposited at the first rate, an apparatus power is 8000-15000 W, a pressure is 1000-4000 mT, a ratio of reaction gases N2O/SiH4 is 20:1˜50:1, and a deposition temperature is 200-300° C.

For example, when the second silicon oxide film is deposited at the second rate, an apparatus power is 4000-8000 W, a pressure is 500-1000 mT, a ratio of reaction gases N2O/SiH4 is 50:1˜90:1, and a deposition temperature is 250-400° C.

For example, the thin film transistor further comprises a gate electrode, and the insulating layer is disposed between the gate electrode and the active layer to serve as a gate insulating layer.

For example, the insulating layer is disposed on the active layer to serve as an etching barrier layer.

For example, the insulating layer further comprises a second insulating layer, the second insulating layer is disposed on a side of the first insulating layer away from the active layer, and the second insulating layer is formed of a silicon nitride film, a silicon oxynitride film or a combination thereof.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1 is a structural schematic view illustrating a thin film transistor of bottom gate type according to embodiments of the disclosure;

FIG. 2 is a structural schematic view illustrating a thin film transistor of top gate type according to embodiments of the disclosure;

FIG. 3 is a structural schematic view illustrating an array substrate according to embodiments of the disclosure, which adopts the thin film transistor of bottom gate type; and

FIG. 4 is a cross-sectional schematic view illustrating the array substrate shown in FIG. 3, which is taken along line A-B.

### DESCRIPTION OF THE EMBODIMENTS

In order to make objects, technical details and advantages of the embodiments of the disclosure apparent, the technical solutions of the embodiment will be described in a clearly and fully understandable way in connection with the drawings related to the embodiments of the disclosure. It is obvious that the described embodiments are just a part but not all of the embodiments of the disclosure. Based on the described embodiments herein, those skilled in the art can obtain other embodiment(s), without any inventive work, which should be within the scope of the disclosure.

Embodiments of the disclosure provide a thin film transistor, which is applied to solve the problem that the interface formed between an insulating layer and an active layer formed of metal oxide in the thin film transistor has many defect states so that the characteristics of the thin film transistor are degraded. The thin film transistor according to the embodiments of the disclosure may be of bottom gate type, or may be of top gate type.

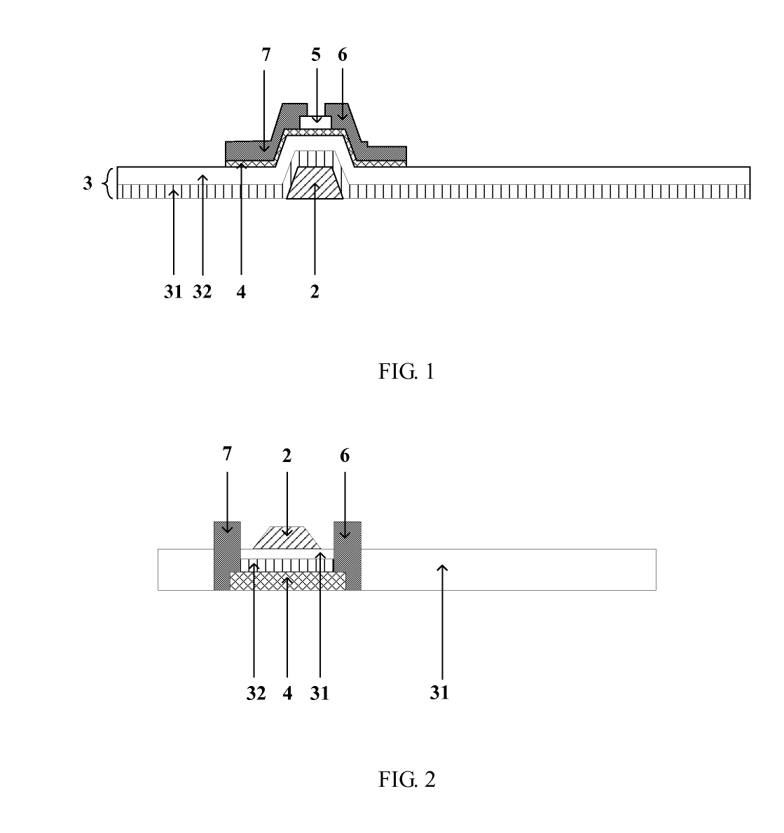

With reference to FIG. 1, the thin film transistor of bottom gate type according to the embodiments of the disclosure is shown. As shown in FIG. 1, the thin film transistor comprises a gate electrode 2, an active layer 4, a gate insulating layer 3 disposed between the gate electrode 2 and the active layer 4, and an etching barrier layer 5, a source electrode 6 and a drain electrode 7 which are disposed on the active layer 4. The gate insulating layer 3 comprises a first insulating layer; the first insulating layer comprises a first silicon oxide film 31 and a second silicon oxide film 32; the second silicon oxide film 32 is formed on the first silicon oxide film; the second silicon oxide film 32 is in direct contact with the active layer 4; and a density of the second silicon oxide film 32 is larger than that of the first silicon oxide film 31.

With reference to FIG. 2, the thin film transistor of top gate type according to the embodiments of this disclosure is shown. As shown in FIG. 2, the thin film transistor comprises a gate electrode 2, an active layer 4, a gate insulating layer 3 disposed between the gate electrode 2 and the active layer 4, a source electrode 6 and a drain electrode 7. The gate insulating layer 3 comprises a first insulating layer; the first insulating layer comprises a first silicon oxide film 31 and a second silicon oxide film 32; the second silicon oxide film 32 is formed below the first silicon oxide film; the second silicon oxide film 32 is in direct contact with the active layer 4; and a density of the second silicon oxide film 32 is larger than that of the first silicon oxide film 31.

For example, a thickness of the second silicon oxide film 32 is 300 Å-800 Å; a total thickness of the first silicon oxide film 31 and the second silicon oxide film 32 is 300 Å-1500 Å.

For example, the gate insulating layer 3 further comprises a second insulating layer (not shown). The second insulating layer is disposed on a side of the first insulating layer away from the active layer. For example, in FIG. 1 and FIG. 2, the second insulating layer is disposed between the first insulating layer and the gate electrode 2. The second insulating layer may be made of silicon nitride, silicon oxynitride, or inorganic insulating material with the same or similar characteristics as silicon nitride or silicon oxynitride. For example, the second insulating layer is formed by a silicon nitride film and a silicon oxynitride film. For another example, the second insulating layer is formed by the silicon nitride film. For another example, the second insulating layer is formed by the silicon oxynitride film. The second insulating layer is strong in preventing water molecules and metal ions from diffusing, so that the diffusion of water molecules and metal ions into the active layer can be effectively prevented and the characteristics of the thin film transistor can be improved. Besides, with respect to the silicon oxide forming the first insulating material, the silicon oxide or silicon oxynitride forming the second insulating layer has a quick etching rate; so in a case that the gate insulating layer 3 is etched to form a via hole, the etching efficiency can be improved if the gate insulating layer 3 comprises the second insulating layer and the adverse influence of long-time etching on the active layer can be avoided.

The first insulating layer and the second insulating layer form the gate insulating layer 3. When the gate insulating layer 3 comprises the second insulating layer, a total thickness of the gate insulating layer 3 for example is 2000 Å-5000 Å. It should be noted that, the above numerical value is only for an example, and the disclosure is not limited thereto.

Besides, for the thin film transistor in the embodiments of the disclosure, the above only describes in detail the case where the insulating layer is the gate insulating layer; the insulating layer may be an etching barrier layer, a passivation layer, etc., which will not be repeated here.

In the thin film transistor according to the embodiments of the disclosure, the insulating layer of the thin film transistor at least comprises the first insulating layer; the first insulating layer comprises the first silicon oxide film and the second silicon oxide film which are different in density; the second silicon oxide film with larger density is in direct contact with the active layer to form a good interface with the metal oxide forming the active layer. Thus, the characteristics of the thin film transistor can be improved.

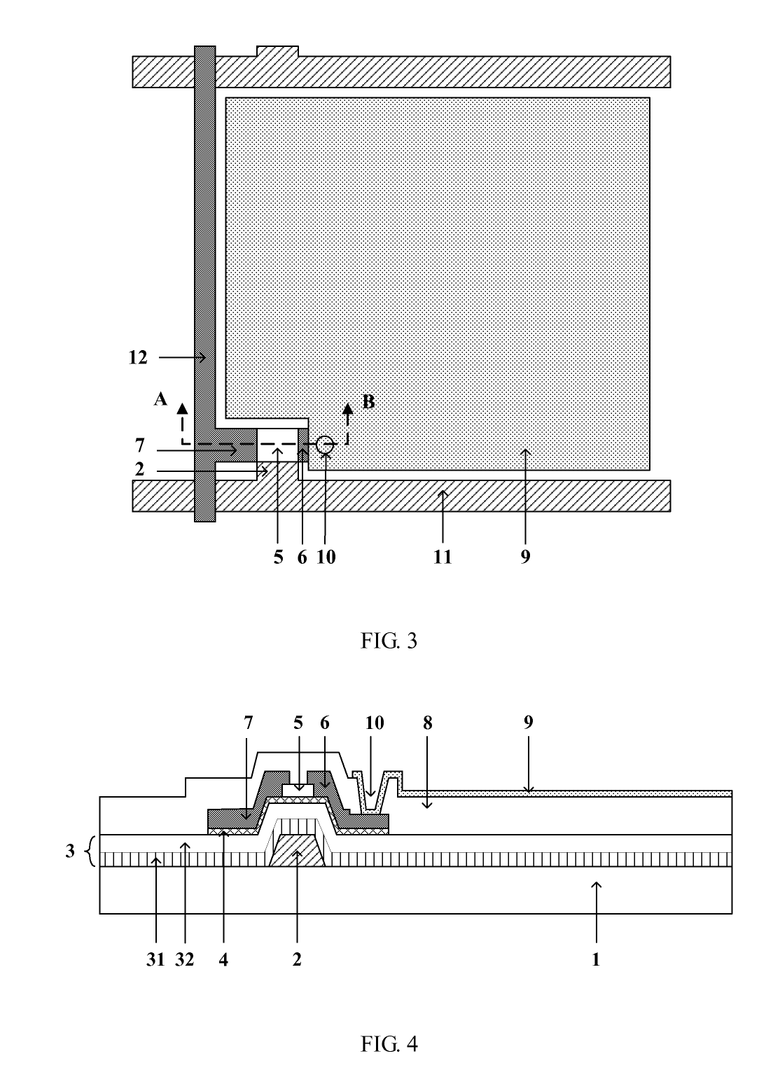

Embodiments of the disclosure further provide an array substrate. The array substrate comprises the thin film transistor according to the above embodiments. Taking the thin film transistor of bottom gate type as an example, and referring to a top view of the array substrate shown in FIG. 3 and a cross-sectional view of the array substrate shown in FIG. 4, the array substrate comprises a substrate 1, and a gate electrode 2 and a gate line 11, a gate insulating layer 3, an active layer 4, an etching barrier layer 5, a source electrode 6, a drain electrode 7 and a data line 12, a passivation layer 8 with a via hole 10, and a pixel electrode 9, which are sequentially disposed on the substrate 1. For example, the active layer 4 is made of metal oxide. The gate insulating layer 3 comprises a first insulating layer formed of a first silicon oxide film 31 and a second silicon oxide film 32; the second silicon oxide film 32 is in direct contact with the active layer 4; and a density of the second silicon oxide film 32 is larger than that of the first silicon oxide film 31.

For example, a thickness of the first insulating layer is 300 Å-1500 Å.

For example, a thickness of the second silicon oxide film is 300 Å-800 Å.

For example, the gate insulating layer 3 further comprises a second gate insulating layer formed of a silicon nitride film and/or a silicon oxynitride film.

The gate line 11 and the gate electrode 2 are disposed in a same layer. For example, the gate line 11 and the gate electrode 2 are made of at least one of Cr, W, Cu, Ti, Ta, and Mo, and the gate line 11 and the gate electrode 2 have a thickness of 4000 Å-15000 Å.

For example, the active layer 4 is made of metal oxide, and the metal oxide is at least one of indium gallium zinc oxide (IGZO), hafnium indium zinc oxide (HIZO), indium zinc oxide (IZO), amorphous indium zinc oxide (a-InZnO), ZnO:F, In₂O₃:Sn, In₂O₃:Mo, Cd₂SnO₄, ZnO:Al, TiO₂:Nb, Cd—Sn—O and other metal oxides with semiconductor characteristics, which shall not be enumerated here one by one.

For example, the etching barrier layer 5 and the passivation layer 8 are formed of a silicon oxide film, a silicon nitride film, a silicon oxynitride film, or a composite structure of at least two films as described above; the etching barrier layer 5 and the passivation layer 8 respectively have a thickness of 1000 Å˜3000 Å. For example, similar to the gate insulating layer 3, the etching barrier layer 5 and the passivation layer 8 respectively have two silicon oxide films. One skilled in the art can change the structures of the etching barrier layer 5 and the passivation layer 8 according to the above descriptions of the gate insulating layer 3, and these change is still within the protection scope of the disclosure and will not be repeatedly described.

The source electrode 6, the drain electrode 7 and the data line 11 are disposed in a same layer. For example, the source electrode 6, the drain electrode 7 and the data line 11 are made of at least one of Cr, W, Cu, Ti, Ta, Mo and the like.

For example, the pixel electrode 9 is made of indium tin oxide (ITO), indium zinc oxide (IZO) or other transparent conductive metal oxide, and the pixel electrode has a thickness of, for example, 300 Å˜1000 Å. The pixel electrode 9 is connected with the source electrode 6 through the via hole 10.

In the array substrate according to the embodiments of the disclosure, the array substrate comprises the thin film transistor, the insulating layer of the thin film transistor at least comprises at least comprises the first insulating layer; the first insulating layer comprises the first silicon oxide film and the second silicon oxide film which are different in density; the second silicon oxide film with larger density is in direct contact with the active layer to form a good interface with the metal oxide forming the active layer. Thus, the characteristics of the thin film transistor can be improved.

Embodiments of the disclosure further provide a display device. The display device comprises the array substrate as described above.

Embodiments of the disclosure further provide a fabrication method of a thin film transistor, which is used for fabricating the above-described thin film transistor. The thin film transistor comprises an active layer and an insulating layer, and the insulating layer comprises a first insulating layer formed of a first silicon oxide film and a second silicon oxide film. The method comprises a step of forming the active layer and a step of forming the insulating layer. The step of forming the insulating layer comprises: depositing the first silicon oxide film at a first rate and depositing the second silicon oxide film in direct contact with the active layer at a second rate. The second rate is less than the first rate.

By depositing the first silicon oxide film and the second silicon oxide film at different rates, the second silicon oxide film with larger density is in direct contact with the active layer so that a good interface is formed between the gate insulating layer and the metal oxide forming the active layer, and the first silicon oxide film is deposited at a quicker deposition rate so that efficiency and yield of the TFT fabrication process can be guaranteed.

For example, when the first silicon oxide film is deposited at the first rate, an apparatus power is 8000-15000 W, a pressure is 1000-4000 mT, a ratio of reaction gases N₂O/SiH₄ is 20:1˜50:1, and a deposition temperature is 200-300° C.

For example, when the second silicon oxide film is deposited at the second rate, the apparatus power is 4000-8000 W, the pressure is 500-1000 mT, the ratio of reaction gases N₂O/SiH₄ is 50:1˜90:1, and the deposition temperature is 250-400° C.

For example, the second rate is 1/5˜4/5 of the first rate.

For example, the insulating layer is a gate insulating layer in direct contact with the active layer or an etching barrier layer in direct contact with the active layer.

For example, the active layer is made of metal oxide.

For example, the fabrication method of the thin film transistor according to the embodiments of the disclosure further comprises a step of forming a gate electrode, and a step of forming a source electrode and a drain electrode.

In the fabrication method of the thin film transistor according to the embodiments of the disclosure, the insulating layer of the thin film transistor comprises the first silicon oxide film and the second silicon oxide film deposited at different deposition rates; the second silicon oxide film deposited at the low rate is in direct contact with the metal oxide forming the active layer; the second silicon oxide film deposited at the low deposition rate has a density larger than that of the first silicon oxide film deposited at the high deposition rate so that the second silicon oxide film has fewer inner defect and a good interface between the second silicon oxide film and the metal oxide is formed. Thus, the characteristics of the thin film transistor can be improved.

In order to more clearly describe the fabrication method of the thin film transistor according to the embodiments of the disclosure, now the description will be further made by taking the thin film transistor of bottom gate type, in which the insulating layer is the gate insulating layer and the gate insulating layer only comprises the first insulating layer, as an example. For example, the fabrication method of the thin film transistor comprises the following steps.

101. Depositing a first metal film on the substrate, and forming the gate electrode through a patterning process.

For example, the first metal film is made of at least one of Cr, W, Cu, Ti, Ta and Mo, and has a deposited thickness of 4000 Å-15000 Å.

102. Depositing the first silicon oxide film at the first rate, and depositing the second silicon oxide film at the second rate, so as to form the first insulating layer of the gate insulating layer, the second rate being less than the first rate.

For example, the second rate is 1/5-4/5 of the first rate, and the specific values are selected as practically required.

For example, when the first silicon oxide film is deposited at the first rate, the apparatus power is 8000-15000 W, the pressure is 1000-4000 mT, the ratio of reaction gases N₂O/SiH₄ is 20:1˜50:1, and the deposition temperature is 200-300° C.

For example, when the second silicon oxide film is deposited at the second rate, the apparatus power is 4000-8000 W, the pressure is 500-1000 mT, the ratio of reaction gases N₂O/SiH₄ is 50:1˜90:1, and the deposition temperature is 250-400° C.

It should be noted that, the above deposition conditions are only illustrative rather than limitative of the embodiments of the disclosure; and the deposition conditions may be set according to the practical requirements.

For example, a thickness of the first silicon oxide film is 300 Å-800 Å, and a total thickness of the first silicon oxide film and the second silicon oxide film is 300 Å-1500 Å.

103. Depositing an active layer film, and forming the active layer through a patterning process. The second silicon oxide film is in direct contact with the active layer film.

For example, the active layer is made of metal oxide material, and the metal oxide material is IGZO, HIZO, IZO, a-InZnO, ZnO:F, In₂O₃:Sn, In₂O₃:Mo, Cd₂SnO₄, ZnO:Al, TiO₂:Nb, or Cd—Sn—O.

104. Depositing an etching barrier film and forming the etching barrier layer through a patterning process.

105. Depositing a second metal film, and forming the source electrode and the drain electrode through a patterning process.

For example, the etching barrier layer formed in the step 104 is formed one of the silicon oxide film, the silicon nitride film, the silicon oxynitride film, or a composite structure of at least two films as described above. For example, a thickness of the etching barrier layer is 1000 Å˜3000 Å. For example, similar to the gate insulating layer, the etching barrier layer has two silicon oxide films. One skilled in the art can change the structure of the etching barrier layer according to the above descriptions of the gate insulating layer, and these change is still within the protection scope of the disclosure and will not be repeatedly described.

For the fabrication of the thin film transistor of top gate type, one skilled in the art can refer to the thin film transistor of top gate type shown in FIG. 2 and the fabrication method of the above thin film transistor of bottom gate type, which will not repeated any more.

The foregoing embodiments merely are exemplary embodiments of the disclosure, and not intended to define the scope of the disclosure, and the scope of the disclosure is determined by the appended claims.

This application claims the priority of Chinese Patent Application No. 201310446633.0 filed on Sep. 26, 2013; the entirety of the Chinese Patent Application is incorporated herein by reference.

1. A thin film transistor, comprising an active layer and an insulating layer adjacent to the active layer, wherein,
the insulating layer comprises a first insulating layer, the first insulating layer comprises a first silicon oxide film and a second silicon oxide film, the second silicon oxide film is in direct contact with the active layer; and
a density of the second silicon oxide is larger than that of the first silicon oxide film.

2. The thin film transistor according to claim 1, wherein a thickness of the first insulating layer is 300 Å-1500 Å.

3. The thin film transistor according to claim 2, wherein a thickness of the second silicon oxide film is 300 Å-800 Å.

4. The thin film transistor according to claim 1, wherein the insulating layer further comprises a second insulating layer, the second insulating layer is disposed on a side of the first insulating layer away from the active layer, and the second insulating layer is formed of a silicon nitride film, a silicon oxynitride film or a combination thereof.

5. The thin film transistor according to claim 1, wherein the active layer is formed of a metal oxide semiconductor.

6. The thin film transistor according to claim 1, wherein the thin film transistor further comprises a gate electrode, and the insulating layer is disposed between the gate electrode and the active layer to serve as a gate insulating layer.

7. The thin film transistor according to claim 1, wherein the insulating layer is disposed on the active layer to serve as an etching barrier layer.

8. (canceled)

9. A display device, comprising the thin film transistor according to claim 1.

10. A fabrication method of a thin film transistor, the thin film transistor comprising an active layer and an insulating layer, the insulating layer comprising a first insulating layer formed of a first silicon oxide film and a second silicon oxide film, the method comprising a step of forming the active layer and a step of forming the insulating layer, wherein
the step of forming the insulating layer comprises: depositing the first silicon oxide film at a first rate, and depositing the second silicon oxide film at a second rate; and
the second silicon oxide film is in direct contact with the active layer, and the second rate is less than the first rate.

11. The method according to claim 10, wherein the second rate is 1/5-4/5 of the first rate.

12. The method according to claim 10, wherein when the first silicon oxide film is deposited at the first rate, an apparatus power is 8000-15000 W, a pressure is 1000-4000 mT, a ratio of reaction gases N₂O/SiH₄ is 20:1˜50:1, and a deposition temperature is 200-300° C.

13. The method according to claim 10, wherein when the second silicon oxide film is deposited at the second rate, an apparatus power is 4000-8000 W, a pressure is 500-1000 mT, a ratio of reaction gases N₂O/SiH₄ is 50:1˜90:1, and a deposition temperature is 250-400° C.

14. The method according to claim 10, wherein the thin film transistor further comprises a gate electrode, and the insulating layer is disposed between the gate electrode and the active layer to serve as a gate insulating layer.

15. The method according to claim 10, wherein the insulating layer is disposed on the active layer to serve as an etching barrier layer.

16. The method according to claim 10, wherein the insulating layer further comprises a second insulating layer, the second insulating layer is disposed on a side of the first insulating layer away from the active layer, and the second insulating layer is formed of a silicon nitride film, a silicon oxynitride film or a combination thereof.

17. The thin film transistor according to claim 2, wherein the insulating layer further comprises a second insulating layer, the second insulating layer is disposed on a side of the first insulating layer away from the active layer, and the second insulating layer is formed of a silicon nitride film, a silicon oxynitride film or a combination thereof.

18. The thin film transistor according to claim 3, wherein the insulating layer further comprises a second insulating layer, the second insulating layer is disposed on a side of the first insulating layer away from the active layer, and the second insulating layer is formed of a silicon nitride film, a silicon oxynitride film or a combination thereof.
